(19) United States
(12) Patent Application Publication
(10) Pub. No.: US 2025/0105847 A1
(43) Pub. Date: Mar. 27, 2025

(54) Techniques For Output Control During Update Of An Integrated Circuit

(71) Applicant: Intel Corporation, Santa Clara, CA (US)

(72) Inventors: Kasper Wszolek, Gdansk (PL); Atul Maheshwari, Portland, OR (US); Ankireddy Nalamalpu, Portland, OR (US); Siang Poh Loh, Sungai Petani (MY)

(73) Assignee: Intel Corporation, Santa Clara, CA (US)

(21) Appl. No.: 18/474,376

(22) Filed: Sep. 26, 2023

(51) Int. Cl. H03K 19/177

(52) U.S. Cl. CPC H03K 19/177

(57) ABSTRACT

An integrated circuit includes an update controller circuit, updatable logic circuits, and an output circuit. The update controller circuit is configured to control an output signal of the output circuit that is provided to an external conductor during reconfiguration of the updatable logic circuits.

### TECHNICAL FIELD

The present disclosure relates to electronic circuit systems and methods, and more particularly, to techniques for output control during update of an integrated circuit.

### BACKGROUND

Configurable integrated circuits can be configured by users to implement desired custom logic functions. In a typical scenario, a logic designer uses computer-aided design (CAD) tools to design a custom circuit design. When the design process is complete, the computer-aided design tools generate configuration data. The configuration data is then loaded into configuration memory elements that configure configurable logic circuits in the integrated circuit to perform the functions of the custom circuit design.

### BRIEF DESCRIPTION OF DRAWINGS

FIG. 1 is a diagram that illustrates an example of a circuit system having an integrated circuit (IC) device that includes an update controller circuit, updatable logic circuits, and input and/or output (IO) circuits.

FIG. 2 is a diagram that illustrates an example of a configurable logic integrated circuit that can implement techniques disclosed herein.

### DETAILED DESCRIPTION

Configurable integrated circuits (ICs) are used in datacenter server platforms as critical elements that control the low-level operational signals of the server platforms. These low-level operational signals can break the operation of a server platform, impact the workloads running on the server platform, etc. if these signals fail. Typically, reconfiguring or reprogramming a configurable integrated circuit (IC) triggers all the input/output circuits of the configurable IC to enter a high impedance state that causes the server platform critical signals to become undefined or floating or default to a state enforced by circuits on a circuit board that supports the configurable IC. These changes to the server platform critical signals typically cause a catastrophic failure of the server.

A configurable integrated circuit (IC) can be reconfigured by loading a new configuration bitstream containing configuration data into the configurable IC during a bitstream update. A bitstream update of a configurable integrated circuit (IC) in a server platform typically requires a power cycle of the entire server. Updating the configurable IC without a power cycle can cause the server platform to crash, because the input/output (IO) circuits in the configurable IC that control voltage regulators in the server platform are re-configured during a bitstream update. The power cycle requirement for a bitstream update creates a significant impact in many server platforms, because a server re-boot can take a substantial amount of time (e.g., 30-40 minutes).

According to some examples disclosed herein, an update controller circuit is provided in a configurable logic IC that controls input and/or output (IO) circuits in the IC during reconfiguration of the configurable logic circuit blocks in the IC. The update controller circuit can, for example, maintain the states of the output signals of output circuits of the IC constant during reconfiguration of the configurable logic circuit blocks in the IC to prevent other system components that receive the output signals from crashing. As another example, the update controller circuit can cause the states of the output signals of the output circuits of the IC to be at predetermined logic states during reconfiguration of the configurable logic circuit blocks in the IC. As yet another example, the update controller circuit can generate predetermined digital or analog waveforms in the output signals of output circuits of the IC during reconfiguration of the configurable logic circuit blocks in the IC.

Most of the platform critical output signals that are generated by configurable integrated circuits (ICs) in server platforms are static (e.g., voltage regulator enable signals). In order to allow for an online bitstream update, these static output signals need to maintain the same states during reconfiguration of the IC. The update controller circuit causes the output circuits in the configurable logic IC to maintain the last states of their output signals during reconfiguration of the IC, until the updated configurable logic circuits in the IC are reconfigured and fully operational. The update controller circuit can control the behavior of the output circuits during a bitstream update of the configurable logic IC. The update controller circuit can be a separate controller circuit in the IC or part of a controller circuit that performs other functions, such as security functions, configuration of the configurable logic circuit blocks in the IC, etc. Additionally, the update controller circuit can, for example, support an immutable or hardened update interface, such as I3C (Improved Inter Integrated Circuit) or the Serial Peripheral Interface (SPI), that is used by the controller circuit that performs the bitstream update (e.g., a baseboard management controller or platform Root Of Trust). I3C and SPI are mentioned herein merely as examples. The update controller circuit can expose many interfaces, and these interfaces can expose update application programming interfaces (APIs) and various update protocols. Additionally, in the example of an I3C dynamic pull-up application, the update controller circuit can also be integrated to be a part of an SDM (Secure Device Manager), Joint Test Action Group (JTAG) subsystem, or other solutions used as configuration controllers.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) logic integrated circuits, such as field programmable gate arrays (FPGAs). As discussed herein, an integrated circuit (IC) can include hard logic and/or soft logic. As used herein, “hard logic” generally refers to circuits in an integrated circuit device that are not programmable by an end user. Although, in some instances, hard logic may be programmable by an end user if the hard logic exposes programmable registers accessible through software or other user logic. The circuits in an integrated circuit device (e.g., in a configurable logic IC) that are configurable by the end user are referred to as “soft logic.”

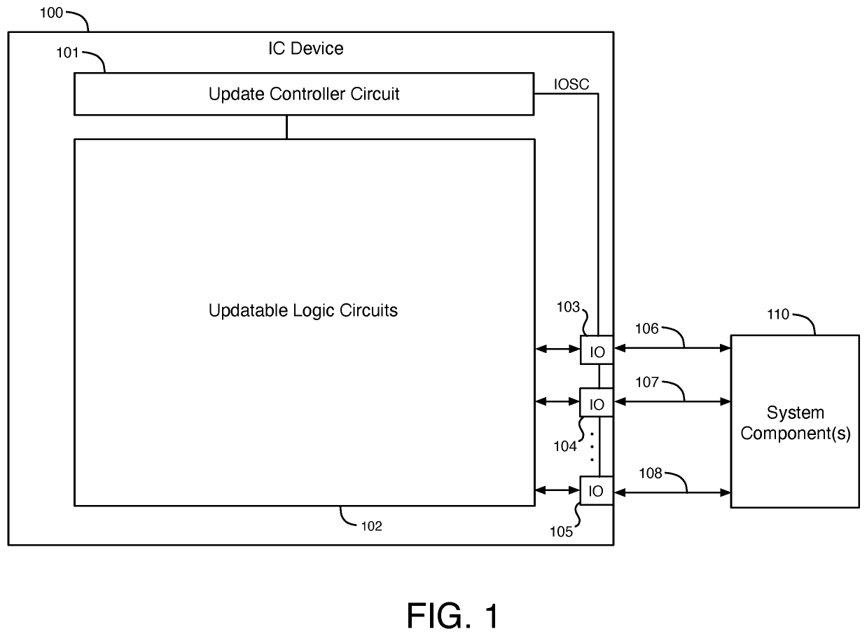

FIG. 1 is a diagram that illustrates an example of a circuit system having an integrated circuit (IC) device 100 that includes an update controller circuit 101, updatable logic circuits 102, and input and/or output (IO) circuits 103, 104, and 105. IC device 100 can be, for example, a configurable logic integrated circuit (IC) (e.g., a field programmable gate array or FPGA), a microprocessor IC (e.g., central processing unit or CPU), a graphics processing unit (GPU) IC, an application specific integrated circuit (ASIC), etc. If IC device 100 is a configurable logic IC, the updatable logic circuits 102 can include blocks of configurable logic circuits (i.e., soft logic). Each of the input/output (IO) circuits 103-105 can include, for example, input buffer circuits, storage circuits (e.g., registers), and/or output buffer circuits. IC device 100 is coupled through external conductors (e.g., conductors 106-108) to one or more system level components 110 (e.g., voltage regulators, processors ICs, etc.) in the circuit system. Although three IO circuits 103-105 and three external conductors 106-108 are shown in FIG. 1, IC 100 can have any number of IO circuits coupled to any number of external conductors. Conductors 106-108 can include, for example, conductive pads, pins, wires, board traces, bumps, balls, etc.

IC device 100 and system components 110 can, for example, be in a server platform. During normal operation, the updatable logic circuits 102 transmit output signals to, and receive input signals from, the system components 110 through IO circuits 103-105 and external conductors 106-108, respectively. During a bitstream update of IC device 100, the updatable logic circuits 102 do not transmit output signals to, or receive input signals from, the system components 110 through IO circuits 103-105 and external conductors 106-108, respectively. Thus, the updatable logic circuits 102 do not control the IO circuits 103-105 during a bitstream update.

Instead, during a bitstream update, a new configuration bitstream is loaded into the IC device 100 to reconfigure the updatable logic circuits 102, while the updatable logic circuits 102 are in a configuration mode. The new configuration bitstream can, for example, be loaded through one or more of the IO circuits 103-105 or other IO circuits of IC device 100 that are not shown in FIG. 1. The new configuration bitstream can be loaded into a configuration controller circuit in IC device 100. The configuration controller circuit can be part of the update controller circuit 101 or a separate controller circuit in IC device 100. The configuration controller circuit provides the new configuration bitstream to the updatable logic circuits 102 to reconfigure the updatable logic circuits 102. As an example, the configuration controller circuit can provide the new configuration bitstream to storage circuits (e.g., configuration random access memory or CRAM) in updatable logic circuits 102. The storage circuits then reconfigure configurable logic circuits (e.g., combinatorial logic circuits) in the updatable logic circuits 102 with the bits in the new configuration bitstream.

While the updatable logic circuits 102 are reconfigured during a bitstream update, the update controller circuit 101 controls the states and/or values (e.g., the logic states) of one or more output signals of the IO circuits 103-105 in order to prevent a crash of one or more of the system components 110 that receive these output signals from IO circuits 103-105 through conductors 106-108, respectively. The update controller circuit 101 controls the values and/or states of the one or more output signals of the IO circuits 103-105 using one or more input/output state control (IOSC) signals. The IOSC signals are provided to one or more inputs of each of the IO circuits 103-105.

During a bitstream update, the update controller circuit 101 adjusts the IOSC signals to control the values and/or states of one or more output signals of the IO circuits 103-105 that are provided through one or more of conductors 106-108, respectively. For example, the update controller circuit 101 can maintain (i.e., freeze) the logic states or analog values of the output signals of IO circuits 103-105 on conductors 106-108 constant during reconfiguration of the updatable logic circuits 102. As a more specific example, the update controller circuit 101 can cause one of the IO circuits 103-105 to freeze the logic state of an output signal that controls a voltage regulator IC that provides a supply voltage to a CPU in a server platform to prevent the CPU from crashing during a bitstream update. As another example, the update controller circuit 101 can cause the logic states or analog values of the output signals of the IO circuits 103-105 on conductors 106-108 to be at predetermined logic states or values during reconfiguration of the updatable logic circuits 102. As yet another example, the update controller circuit 101 can cause the IO circuits 103-105 to generate predetermined digital or analog waveforms in the output signals on conductors 106-108 during reconfiguration of the updatable logic circuits 102. The update controller circuit 101 causes the output signals of the IO circuits 103-105 to be at values that maintain operation of the system components 110, or at least prevent the system components 110 from crashing, during the bitstream update.

After the bitstream update of IC device 100 is complete, the update controller circuit 101 stops controlling the values and/or states of the one or more output signals of the IO circuits 103-105 that are provided through the one or more conductors 106-108, respectively. Update controller circuit 101 returns control of the IO circuits 103-105 to the updatable logic circuits 102. After the bitstream update is complete, the updatable logic circuits 102 return to normal mode again, and resume transmitting output signals to, and receiving input signals from, the system components 110 through IO circuits 103-105 and external conductors 106-108, respectively.

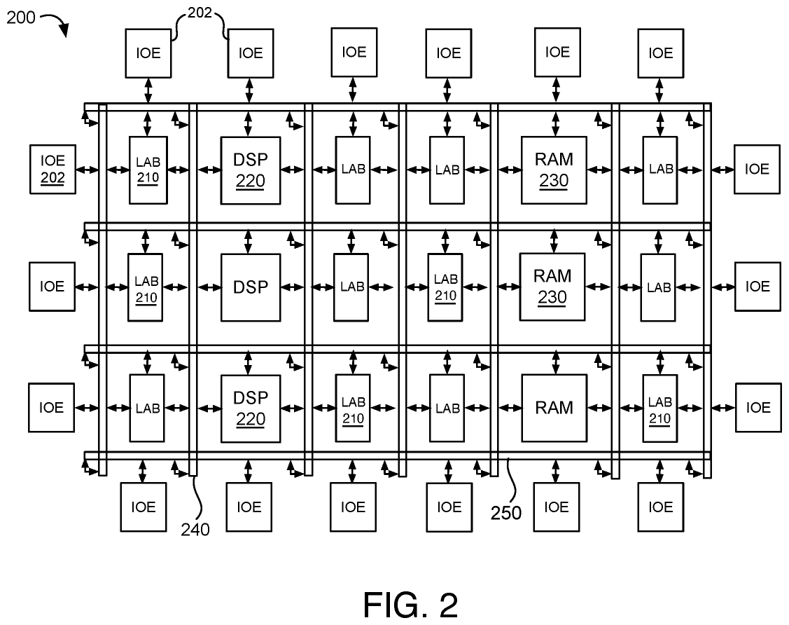

Figure (FIG. 2 is a diagram that illustrates an example of a configurable logic IC 200 that can implement techniques disclosed herein. IC device 100 can include the architecture of configurable logic IC 200 according to an example. As shown in FIG. 2, the configurable logic IC 200 includes a two-dimensional array of configurable functional circuit blocks, including configurable logic array blocks (LABs) 210 and other functional circuit blocks, such as random access memory (RAM) blocks 230 and digital signal processing (DSP) blocks 220. Functional blocks such as LABs 210 can include smaller programmable logic circuits (e.g., logic elements, logic blocks, or adaptive logic modules) that receive input signals and perform custom functions on the input signals to produce output signals.

In addition, configurable logic IC 200 can have input/output elements (IOEs) 202 for driving signals off of configurable logic IC 200 and for receiving signals from other devices. IOEs 202 may include parallel input/output circuitry, serial data transceiver circuitry, differential receiver and transmitter circuitry, or other circuitry used to connect one integrated circuit to another integrated circuit. As shown, IOEs 202 may be located around the periphery of the chip. If desired, the configurable logic IC 200 may have IOEs 202 arranged in different ways. For example, IOEs 202 may form one or more columns, rows, or islands of input/output elements that may be located anywhere on the configurable IC 200.

The configurable logic IC 200 can also include programmable interconnect circuitry in the form of vertical routing channels 240 (i.e., interconnects formed along a vertical axis of configurable logic IC 200) and horizontal routing channels 250 (i.e., interconnects formed along a horizontal axis of configurable logic IC 200), each routing channel including at least one track to route at least one wire.

Note that other routing topologies, besides the topology of the interconnect circuitry depicted in FIG. 2, may be used. For example, the routing topology may include wires that travel diagonally or that travel horizontally and vertically along different parts of their extent as well as wires that are perpendicular to the device plane in the case of three dimensional integrated circuits. The driver of a wire may be located at a different point than one end of a wire.

Furthermore, it should be understood that embodiments disclosed herein with respect to FIG. 1 may be implemented in any integrated circuit or electronic system. If desired, the functional blocks of such an integrated circuit may be arranged in more levels or layers in which multiple functional blocks are interconnected to form still larger blocks. Other device arrangements may use functional blocks that are not arranged in rows and columns.

Configurable logic IC 200 may contain programmable memory elements. Memory elements may be loaded with configuration data using IOEs 202. Once loaded, the memory elements each provide a corresponding static control signal that controls the operation of an associated configurable functional block (e.g., LABs 210, DSP blocks 220, RAM blocks 230, or IOEs 202). The configuration data can set the functions of the configurable functional circuit blocks (soft logic) in IC 200.

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The programmable memory elements may be organized in a configuration memory array consisting of rows and columns. A data register that spans across all columns and an address register that spans across all rows may receive configuration data. The configuration data may be shifted onto the data register. When the appropriate address register is asserted, the data register writes the configuration data to the configuration memory bits of the row that was designated by the address register.

In certain embodiments, configurable logic IC 200 may include configuration memory that is organized in sectors, whereby a sector may include the configuration RAM bits that specify the functions and/or interconnections of the subcomponents and wires in or crossing that sector. Each sector may include separate data and address registers.

The configurable IC of FIG. 2 is merely one example of an IC that can include embodiments disclosed herein. The embodiments disclosed herein may be incorporated into any suitable integrated circuit or system. For example, the embodiments disclosed herein may be incorporated into numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein may be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is an integrated circuit comprising: an update controller circuit; updatable logic circuits; and a first output circuit, wherein the update controller circuit is configured to control a first output signal of the first output circuit that is provided to a first external conductor during reconfiguration of the updatable logic circuits.
In Example 2, the integrated circuit of Example 1 further comprises: a second output circuit, wherein the update controller circuit is further configured to control a second output signal of the second output circuit that is provided to a second external conductor during reconfiguration of the updatable logic circuits.
In Example 3, the integrated circuit of any one of Examples 1-2 may optionally include, wherein the updatable logic circuits are configurable to control the first output signal of the first output circuit during a normal mode of operation.
In Example 4, the integrated circuit of any one of Examples 1-3 may optionally include, wherein the update controller circuit is configured to maintain a state of the first output signal of the first output circuit constant during reconfiguration of the updatable logic circuits.
In Example 5, the integrated circuit of any one of Examples 1-4 may optionally include, wherein the update controller circuit is configured to cause the first output signal of the first output circuit to be at a predetermined state during reconfiguration of the updatable logic circuits.
In Example 6, the integrated circuit of any one of Examples 1-5 may optionally include, wherein the update controller circuit is configured to cause the first output signal of the first output circuit to have a predetermined waveform during reconfiguration of the updatable logic circuits.
In Example 7, the integrated circuit of any one of Examples 1-6 may optionally include, wherein the integrated circuit is a configurable logic integrated circuit.
In Example 8, the integrated circuit of any one of Examples 1-7 may optionally include, wherein the first output signal is provided through the first external conductor to a system component during reconfiguration of the updatable logic circuits.
In Example 9, the integrated circuit of any one of Examples 1-8 may optionally include, wherein the update controller circuit is further configured to control the first output signal of the first output circuit using control signals provided to the first output circuit.
Example 10 is a method for updating a circuit system, the method comprising: providing a first output from a first updatable logic circuit in an integrated circuit through a first output circuit in the integrated circuit to a first external conductor during a first normal mode of operation of the first updatable logic circuit; and controlling the first output provided from the first output circuit to the first external conductor during an update of the first updatable logic circuit using an update controller circuit in the integrated circuit.
In Example 11, the method of Example 10 may optionally include, wherein controlling the first output provided from the first output circuit to the first external conductor comprises maintaining a value of the first output constant during the update of the first updatable logic circuit using the update controller circuit.
In Example 12, the method of any one of Examples 10-11 may optionally include, wherein controlling the first output provided from the first output circuit to the first external conductor comprises causing the first output to be a predetermined value during the update of the first updatable logic circuit.
In Example 13, the method of any one of Examples 10-12 further comprises: providing a second output from a second updatable logic circuit in the integrated circuit through a second output circuit in the integrated circuit to a second external conductor during a second normal mode of operation of the second updatable logic circuit; and controlling the second output provided from the second output circuit to the second external conductor during an update of the second updatable logic circuit using the update controller circuit.
In Example 14, the method of any one of Examples 10-13 may optionally include, wherein the integrated circuit is a configurable logic integrated circuit.
In Example 15, the method of any one of Examples 10-14 may optionally include, wherein controlling the first output provided from the first output circuit to the first external conductor comprises controlling a value of the first output during the update of the first updatable logic circuit using a control signal generated by the update controller circuit.
Example 16 is a circuit system comprising: a system component; and an integrated circuit comprising an update controller circuit, a reconfigurable logic circuit, and a first output circuit, wherein the update controller circuit is configured to set a state of a first output signal provided from the first output circuit to the system component during reconfiguration of the reconfigurable logic circuit.
In Example 17, the circuit system of Example 16 may optionally include, wherein the update controller circuit is configured to maintain the state of the first output signal provided from the first output circuit to the system component constant during the reconfiguration of the reconfigurable logic circuit.
In Example 18, the circuit system of any one of Examples 16-17 may optionally include, wherein the update controller circuit is configured to set the state of the first output signal provided from the first output circuit to the system component to at least one predefined state during the reconfiguration of the reconfigurable logic circuit.
In Example 19, the circuit system of any one of Examples 16-18 may optionally include, wherein the integrated circuit further comprises a second output circuit, and wherein the update controller circuit is configured to set a state of a second output signal provided from the second output circuit to the system component during reconfiguration of the reconfigurable logic circuit.
In Example 20, the circuit system of any one of Examples 16-19 may optionally include, wherein the reconfigurable logic circuit generates the first output signal that is provided to the system component using the first output circuit during a normal mode of operation of the reconfigurable logic circuit.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

1. An integrated circuit comprising:
an update controller circuit;
updatable logic circuits; and
a first output circuit, wherein the update controller circuit is configured to control a first output signal of the first output circuit that is provided to a first external conductor during reconfiguration of the updatable logic circuits.

2. The integrated circuit of claim 1 further comprising:
a second output circuit, wherein the update controller circuit is further configured to control a second output signal of the second output circuit that is provided to a second external conductor during reconfiguration of the updatable logic circuits.

3. The integrated circuit of claim 1, wherein the updatable logic circuits are configurable to control the first output signal of the first output circuit during a normal mode of operation.

4. The integrated circuit of claim 1, wherein the update controller circuit is configured to maintain a state of the first output signal of the first output circuit constant during reconfiguration of the updatable logic circuits.

5. The integrated circuit of claim 1, wherein the update controller circuit is configured to cause the first output signal of the first output circuit to be at a predetermined state during reconfiguration of the updatable logic circuits.

6. The integrated circuit of claim 1, wherein the update controller circuit is configured to cause the first output signal of the first output circuit to have a predetermined waveform during reconfiguration of the updatable logic circuits.

7. The integrated circuit of claim 1, wherein the integrated circuit is a configurable logic integrated circuit.

8. The integrated circuit of claim 1, wherein the first output signal is provided through the first external conductor to a system component during reconfiguration of the updatable logic circuits.

9. The integrated circuit of claim 1, wherein the update controller circuit is further configured to control the first output signal of the first output circuit using control signals provided to the first output circuit.

10. A method for updating a circuit system, the method comprising:
providing a first output from a first updatable logic circuit in an integrated circuit through a first output circuit in the integrated circuit to a first external conductor during a first normal mode of operation of the first updatable logic circuit; and
controlling the first output provided from the first output circuit to the first external conductor during an update of the first updatable logic circuit using an update controller circuit in the integrated circuit.

11. The method of claim 10, wherein controlling the first output provided from the first output circuit to the first external conductor comprises maintaining a value of the first output constant during the update of the first updatable logic circuit using the update controller circuit.

12. The method of claim 10, wherein controlling the first output provided from the first output circuit to the first external conductor comprises causing the first output to be a predetermined value during the update of the first updatable logic circuit.

13. The method of claim 10 further comprising:
providing a second output from a second updatable logic circuit in the integrated circuit through a second output circuit in the integrated circuit to a second external conductor during a second normal mode of operation of the second updatable logic circuit; and
controlling the second output provided from the second output circuit to the second external conductor during an update of the second updatable logic circuit using the update controller circuit.

14. The method of claim 10, wherein the integrated circuit is a configurable logic integrated circuit.

15. The method of claim 10, wherein controlling the first output provided from the first output circuit to the first external conductor comprises controlling a value of the first output during the update of the first updatable logic circuit using a control signal generated by the update controller circuit.

16. A circuit system comprising:
a system component; and
an integrated circuit comprising an update controller circuit, a reconfigurable logic circuit, and a first output circuit, wherein the update controller circuit is configured to set a state of a first output signal provided from the first output circuit to the system component during reconfiguration of the reconfigurable logic circuit.

17. The circuit system of claim 16, wherein the update controller circuit is configured to maintain the state of the first output signal provided from the first output circuit to the system component constant during the reconfiguration of the reconfigurable logic circuit.

18. The circuit system of claim 16, wherein the update controller circuit is configured to set the state of the first output signal provided from the first output circuit to the system component to at least one predefined state during the reconfiguration of the reconfigurable logic circuit.

19. The circuit system of claim 16, wherein the integrated circuit further comprises a second output circuit, and wherein the update controller circuit is configured to set a state of a second output signal provided from the second output circuit to the system component during reconfiguration of the reconfigurable logic circuit.

20. The circuit system of claim 16, wherein the reconfigurable logic circuit generates the first output signal that is provided to the system component using the first output circuit during a normal mode of operation of the reconfigurable logic circuit.
